(19) United States
(12) Patent Application Publication
(10) Pub. No.: US 2026/0245639 A1
(43) Pub. Date: Aug. 20, 2026

(54) BACKGROUND DATA REFRESH IN STORAGE DEVICES

(71) Applicant: SK Hynix NAND Product Solutions Corp. (dba Solidigm), Rancho Cordova, CA (US)

(72) Inventor: Zion Kwok, Burnaby (CA)

(21) Appl. No.: 19/002,526

(22) Filed: Dec. 26, 2024

(51) Int. Cl. G11C 16/34; G11C 16/28

(52) U.S. Cl. CPC G11C 16/3431; G11C 16/28; G11C 16/3404

(57) ABSTRACT

This application is directed to implementing a background data refresh on a non-volatile memory of a memory device. The non-volatile memory includes a plurality of X-level memory cells, and X is equal to an integer number greater than 1. The memory device applies a readout voltage based on a reference voltage to read data stored in the plurality of X-level memory cells, and the plurality of X-level memory cells are configured to store a plurality of successive integer values. Based on the readout voltage, the memory device identifies a subset of memory cells of the plurality of memory cells storing a first value of the plurality of successive integer values, and the first value is the largest integer value stored by the plurality of successive integer values. The memory device programs the subset of memory cells to re-write the first value in the subset of memory cells.

### RELATED APPLICATION

This application relates to U.S. patent application Ser. No. ______ (Attorney Docket No. 132251-01-5061-US), filed ______, titled “Balanced Codes for Moving Read References in Memory Devices,” which is incorporated by reference in its entirety.

### TECHNICAL FIELD

This application relates generally to storage management including, but not limited to, methods, systems, and non-transitory computer-readable media for managing data storage in a memory device (e.g., a solid-state drive).

### BACKGROUND

Memory is applied in a computer system to store instructions and data. The data are processed by one or more processors of the computer system according to the instructions stored in the memory. Multiple memory units are used in different portions of the computer system to serve different functions. Specifically, the computer system includes non-volatile memory that acts as secondary memory to keep data stored thereon if the computer system is decoupled from a power source. Examples of the secondary memory include, but are not limited to, hard disk drives (HDDs) and solid-state drives (SSDs). Over time, some memory contents degrade and have increased numbers of bit errors. For example, bit errors can be introduced into memory pages due to program disturb, read disturb, and loss of retention. If too many bit errors accumulate, corresponding data are uncorrectable. Particularly, SSD data needs to be balanced by wear leveling to ensure that data is written evenly across the entire drive, preventing specific areas from wearing out too quickly and significantly extending the lifespan of the SSD, as each cell within the flash memory has a limited number of write cycles before failing; essentially, by distributing writes evenly, the SSD can maximize its lifespan and reduce a chance of having bit errors.

An alternative approach to mitigate bit error accumulation is to periodically refresh the memory contents by doing read-modify-write. Under most circumstances, a memory page has few errors, and however, periodic refreshes of the memory still uses a portion of an input/output (I/O) bandwidth and a power budget of the memory device, leaving less I/O bandwidth to process the read or write requests received from the host. It would be beneficial to develop a fast and economical solution to implement background refreshes.

### SUMMARY

Some embodiments of this application are directed to methods, systems, devices, non-transitory computer-readable media for balancing data storage within a data block in a non-volatile memory of a memory device (e.g., an SSD). The data block has a plurality of data bits that are transformed to have equal numbers of “0” an “1.” In some embodiments, data bits of the data block are selectively flipped to balance the data block. In some embodiments, extra data bits added to balance the data block. In some embodiments, a first bit position is identified in the data block to identify at least a first subset of data bits, such that the data block is balanced when the first subset of data bits are flipped jointly. In some embodiments, two or more bit positions are identified in the data block to identify two or more subsets of successive data bits in the data block, such that the data block is balanced when two or more subsets of successive data bits are flipped jointly. Further, in some embodiments, an SSD or a portion of the SSD is divided into a plurality of areas each of which stores a block of data bits, and each data block is independently balanced. By these means, data is written evenly within the SSD, preventing specific areas from wearing out too quickly, significantly extending the lifespan of the SSD, and reducing a chance of having bit errors in the SSD.

In one aspect, a method is implemented at a memory device (e.g., a solid-state drive (SSD)) for balancing data storage. The method includes extracting a structured data block and metadata from a memory block of the non-volatile memory. The structured data block includes a plurality of data items each of which is stored in a respective memory cell of the memory block. The method further includes identifying a first subset of data items of the plurality of data items based on the metadata, and the plurality of data items further include a second subset of data items. The method further includes flipping the first subset of data items to generate a set of flipped data items, and replacing the first subset of data items of the structured data block with the set of flipped data to generate a target data block.

In some embodiments, the method further includes, based on the metadata, determining a first data position that separates the first subset of data items and the second subset of data items in the structured data block. The first subset of data items is arranged in the structured data block before the first data position, and the second subset of data items starts from the first data position. Further, in some embodiments, each and every bit of the first subset of data items are flipped to generate the set of flipped data items.

A read reference voltage in an SSD refers to a specific voltage level used by a memory controller to read data from the flash memory cells, acting as a threshold to determine whether a memory cell is storing one of two consecutive data levels (e.g., “0” and “1” in a single level cell memory, “001” and “010” in a TLC memory) by comparing its read voltage against the read reference voltage. The read reference voltage plays a crucial role in reliable data retrieval, e.g., when dealing with potential variations in cell voltage due to wear and tear on the SSD. In some embodiments, the read reference voltage can be moved to minimize the number of bit errors.

Some embodiments of this application are directed to methods, systems, devices, non-transitory computer-readable media for applying a partial background refresh in a non-volatile memory of a memory device (e.g., an SSD) to keep a substantially high data fidelity level for the memory device in an efficient manner. In some embodiments, background data refreshes are implemented periodically on a regular schedule, thereby mitigating accumulation of error bits caused by a charge leakage of memory cells of the memory device. For example, in a triple-level cell (TLC) NAND flash memory chip, charge leakage affects memory cells storing the highest data level 7 (L7), and the data level L7 is a program level with the highest threshold voltages (Vt) among eight data levels of the TLC NAND flash memory chip.

In another aspect of this application, a method is implemented to refresh a non-volatile memory of a memory device. The non-volatile memory include a plurality of X-level memory cells, and X is equal to an integer number greater than 1. The method includes applying a read voltage based on a read reference to read data stored in the plurality of X-level memory cells, and the plurality of X-level memory cells are configured to store a plurality of successive integer values. The method further includes, based on the read voltage, identifying a subset of the plurality of memory cells storing a first value of the plurality of successive integer values. The first value is greater than a remainder of the plurality of successive integer values. The method further includes programming the subset of the plurality of memory cells with the first value.

In some embodiments, the method further includes identifying a voltage range based on the read reference, and applying the read voltage includes increasing the read voltage in the voltage range. The method further includes, while increasing the read voltage in the voltage range, determining that each of the subset of the plurality of memory cells has a respective transistor that is switched from an off state to an on state.

In some embodiments, the method further includes aborting programming the remainder of the plurality of memory cells in a corresponding background data refresh, and the subset of the plurality of memory cells is programmed according to a background refresh rate.

In some embodiments, the plurality of X-level memory cells have a plurality of peak probabilities at a plurality of feature threshold voltages for storing the plurality of successive integer values. The method further includes identifying the read reference in a range between two largest feature threshold voltages of the plurality of feature threshold voltages, wherein each of the subset of the plurality memory cells storing the first value has a respective threshold voltage greater than the read reference.

Some implementations of this application include an electronic device, an electronic system, a memory device, or a memory system. The electronic device, the electronic system, the memory device, or the memory system includes a memory controller, a non-volatile memory, and memory having instructions stored thereon, which when executed by the memory controller cause the memory controller to perform any of the above methods.

Some implementations include a non-transitory computer readable storage medium storing one or more programs. The one or more programs include instructions, which when executed by a memory device cause the memory device to implement any of the above methods.

In some embodiments, the above methods, electronic devices, or non-transitory computer readable storage medium for controlling error correction or background data refresh are also used in data communication (e.g., wireless communication using 5G or Wi-Fi technology, satellite communications, Ethernet communication, and communication via fiber Optic networks).

These illustrative embodiments and implementations are mentioned not to limit or define the disclosure, but to provide examples to aid understanding thereof. Additional embodiments are discussed in the Detailed Description, and further description is provided there.

### BRIEF DESCRIPTION OF THE DRAWINGS

For a better understanding of the various described implementations, reference should be made to the Detailed Description below, in conjunction with the following drawings in which like reference numerals refer to corresponding parts throughout the figures.

FIG. 1 is a block diagram of an example system module in a typical electronic device in accordance with some embodiments.

FIG. 2 is a block diagram of a memory system of an example electronic device having one or more memory access queues, in accordance with some embodiments.

FIG. 3 is a block diagram of an example integrity check system of a memory system for processing a codeword, in accordance with some embodiments.

FIG. 4A illustrates an example memory cell threshold voltage probability distribution of a single-level cell (SLC) memory cell, in accordance with some embodiments.

FIGS. 4B and 4C illustrate example memory cell threshold voltage probability distributions of a multi-level cell (MLC) memory cell and an TLC memory cell, in accordance with some embodiments, respectively.

FIG. 5 is an example memory block storing a structured data block in which data bits are flipped for coding balancing, in accordance with some embodiments.

FIG. 6 is a flow diagram of an example process of moving a read reference voltage of a memory block, in accordance with some embodiments.

FIG. 7 is a flow diagram of another example process of moving a read reference voltage of a memory block, in accordance with some embodiments.

FIG. 8 is a flow diagram of an example method for balancing codes in a memory device, in accordance with some embodiments.

FIG. 9 illustrates an example threshold voltage probability distribution for a data block having a plurality of data items, in accordance with some embodiments.

FIG. 10 illustrates another example threshold voltage probability distribution for a data block having a plurality of data items, in accordance with some embodiments.

FIG. 11 is a flow diagram of an example method for refreshing data (e.g., in a background refresh) in a memory device, in accordance with some embodiments.

Like reference numerals refer to corresponding parts throughout the several views of the drawings.

### DETAILED DESCRIPTION

Reference will now be made in detail to specific embodiments, examples of which are illustrated in the accompanying drawings. In the following detailed description, numerous non-limiting specific details are set forth in order to assist in understanding the subject matter presented herein. But it will be apparent to one of ordinary skill in the art that various alternatives may be used without departing from the scope of claims and the subject matter may be practiced without these specific details. For example, it will be apparent to one of ordinary skill in the art that the subject matter presented herein can be implemented on many types of electronic devices using secondary storage.

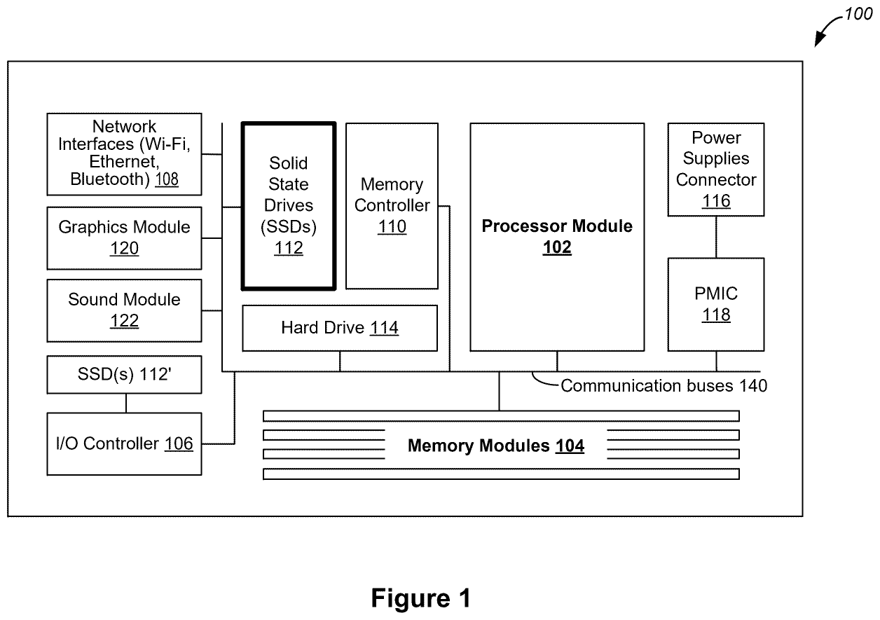

FIG. 1 is a block diagram of an example system module 100 in a typical electronic system in accordance with some embodiments. The system module 100 in this electronic system includes at least a processor module 102, memory modules 104 for storing programs, instructions and data, an input/output (I/O) controller 106, one or more communication interfaces such as network interfaces 108, and one or more communication buses 140 for interconnecting these components. In some embodiments, the I/O controller 106 allows the processor module 102 to communicate with an I/O device (e.g., a keyboard, a mouse or a trackpad) via a universal serial bus interface. In some embodiments, the network interfaces 108 includes one or more interfaces for Wi-Fi, Ethernet and Bluetooth networks, each allowing the electronic system to exchange data with an external source, e.g., a server or another electronic system. In some embodiments, the communication buses 140 include circuitry (sometimes called a chipset) that interconnects and controls communications among various system components included in system module 100.

In some embodiments, the memory modules 104 include high-speed random-access memory, such as static random-access memory (SRAM), double data rate (DDR) dynamic random-access memory (DRAM), or other random-access solid state memory devices. In some embodiments, the memory modules 104 include non-volatile memory, such as one or more magnetic disk storage devices, optical disk storage devices, flash memory devices, or other non-volatile solid state storage devices. In some embodiments, the memory modules 104, or alternatively the non-volatile memory device(s) within the memory modules 104, include a non-transitory computer readable storage medium. In some embodiments, memory slots are reserved on the system module 100 for receiving the memory modules 104. Once inserted into the memory slots, the memory modules 104 are integrated into the system module 100.

In some embodiments, the system module 100 further includes one or more components selected from a memory controller 110, SSD(s) 112, an HDD 114, power management integrated circuit (PMIC) 118, a graphics module 120, and a sound module 122. The memory controller 110 is configured to control communication between the processor module 102 and memory components, including the memory modules 104, in the electronic system. The SSD(s) 112 are configured to apply integrated circuit assemblies to store data in the electronic system, and in many embodiments, are based on NAND or NOR memory configurations. The HDD 114 is a conventional data storage device used for storing and retrieving digital information based on electromechanical magnetic disks. The power supply connector 116 is electrically coupled to receive an external power supply. The PMIC 118 is configured to modulate the received external power supply to other desired DC voltage levels, e.g., 5V, 3.3V or 1.8V, as required by various components or circuits (e.g., the processor module 102) within the electronic system. The graphics module 120 is configured to generate a feed of output images to one or more display devices according to their desirable image/video formats. The sound module 122 is configured to facilitate the input and output of audio signals to and from the electronic system under control of computer programs.

Alternatively or additionally, in some embodiments, the system module 100 further includes SSD(s) 112′ coupled to the I/O controller 106 directly. Conversely, the SSDs 112 are coupled to the communication buses 140. In an example, the communication buses 140 operates in compliance with Peripheral Component Interconnect Express (PCIe or PCI-E), which is a serial expansion bus standard for interconnecting the processor module 102 to, and controlling, one or more peripheral devices and various system components including components 110-122.

Further, one skilled in the art knows that other non-transitory computer readable storage media can be used, as new data storage technologies are developed for storing information in the non-transitory computer readable storage media in the memory modules 104, SSD(s) 112 or 112′, and HDD 114. These new non-transitory computer readable storage media include, but are not limited to, those manufactured from biological materials, nanowires, carbon nanotubes and individual molecules, even though the respective data storage technologies are currently under development and yet to be commercialized.

Some implementations of this application are directed to an integrity check process implemented by a memory system (e.g., SSD(s) 112, memory module 104, HDD 114, memory controller 110), which stores codeword symbols including integrity data, e.g., LDPC codes. The integrity check process is also called a decoding process implementing between variable nodes and check nodes. The variable nodes correspond to the codeword symbols extracted from the memory system. Each check node correspond to a distinct set of variable nodes, and has check node data configured to identify bit errors in the codeword symbols corresponding to the distinct set of variable nodes.

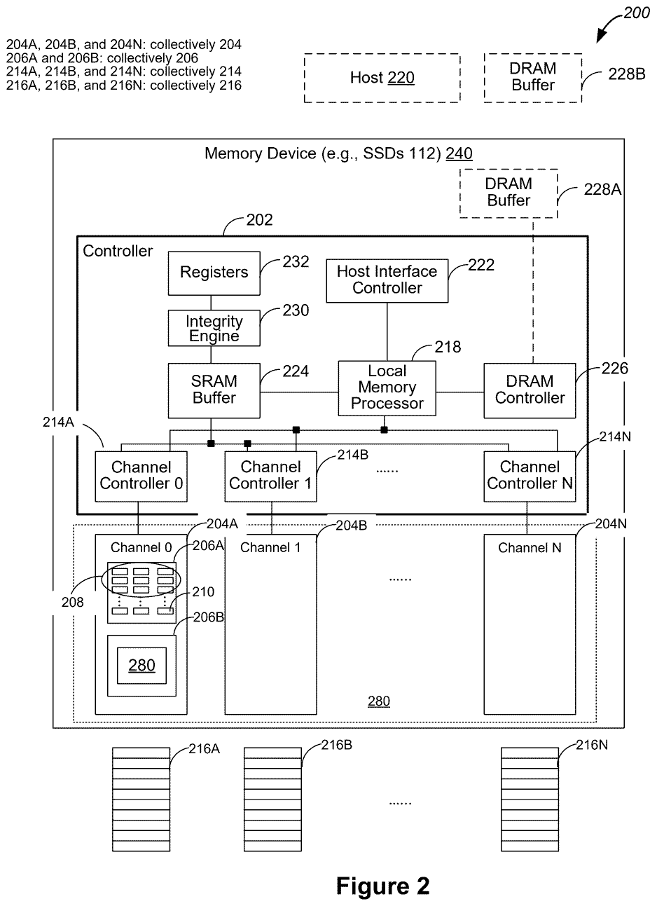

FIG. 2 is a block diagram of a memory system 200 of an example electronic device having one or more memory access queues, in accordance with some embodiments. The memory system 200 is coupled to a host device 220 (e.g., a processor module 102 in FIG. 1) and configured to store instructions and data for an extended time, e.g., when the electronic device sleeps, hibernates, or is shut down. The host device 220 is configured to access the instructions and data stored in the memory system 200 and process the instructions and data to run an operating system and execute user applications. The memory system 200 includes one or more memory devices 240 (e.g., SSD(s)). Each memory device 240 further includes a controller 202 and a plurality of memory channels 204 (e.g., channel 204A, 204B, and 204N). Each memory channel 204 includes a plurality of memory cells. The controller 202 is configured to execute firmware level software to bridge the plurality of memory channels 204 to the host device 220. In some embodiments, each memory device 240 is formed on a printed circuit board (PCB).

Each memory channel 204 includes one or more memory packages 206 (e.g., two memory dies). In an example, each memory package 206 (e.g., memory package 206A or 206B) corresponds to a memory die. Each memory package 206 includes a plurality of memory planes 208, and each memory plane 208 further includes a plurality of memory pages 210. Each memory page 210 includes an ordered set of memory cells, and each memory cell is identified by a respective physical address. In some embodiments, the memory device 240 includes a plurality of superblocks. Each superblock includes a plurality of memory blocks each of which further includes a plurality of memory pages 210. For each superblock, the plurality of memory blocks are configured to be written into and read from the memory system via a memory input/output (I/O) interface concurrently. Optionally, each superblock groups memory cells that are distributed on a plurality of memory planes 208, a plurality of memory channels 204, and a plurality of memory dies 206. In an example, each superblock includes at least one set of memory pages, where each page is distributed on a distinct one of the plurality of memory dies 206, has the same die, plane, block, and page designations, and is accessed via a distinct channel of the distinct memory die 206. In another example, each superblock includes at least one set of memory blocks, where each memory block is distributed on a distinct one of the plurality of memory dies 206 includes a plurality of pages, has the same die, plane, and block designations, and is accessed via a distinct channel of the distinct memory die 206. The memory device 240 stores information of an ordered list of superblocks in a cache of the memory device 240. In some embodiments, the cache is managed by a host driver of the host device 220, and called a host managed cache (HMC).

In some embodiments, the memory device 240 includes a single-level cell (SLC) NAND flash memory chip, and each memory cell stores a single data bit. In some embodiments, the memory device 240 includes a multi-level cell (MLC) NAND flash memory chip, and each memory cell of the MLC NAND flash memory chip stores 2 data bits. In an example, each memory cell of a triple-level cell (TLC) NAND flash memory chip stores 3 data bits. In another example, each memory cell of a quad-level cell (QLC) NAND flash memory chip stores 4 data bits. In yet another example, each memory cell of a penta-level cell (PLC) NAND flash memory chip stores 5 data bits. In some embodiments, each memory cell can store any suitable number of data bits. Compared with the non-SLC NAND flash memory chips (e.g., MLC SSD, TLC SSD, QLC SSD, PLC SSD), the SSD that has SLC NAND flash memory chips operates with a higher speed, a higher reliability, and a longer lifespan, and however, has a lower device density and a higher price.

Each memory channel 204 is coupled to a respective channel controller 214 (e.g., controller 214A, 214B, or 214N) configured to control internal and external requests to access memory cells in the respective memory channel 204. In some embodiments, each memory package 206 (e.g., each memory die) corresponds to a respective queue 216 (e.g., queue 216A, 216B, or 216N) of memory access requests. In some embodiments, each memory channel 204 corresponds to a respective queue 216 of memory access requests. Further, in some embodiments, each memory channel 204 corresponds to a distinct and different queue 216 of memory access requests. In some embodiments, a subset (less than all) of the plurality of memory channels 204 corresponds to a distinct queue 216 of memory access requests. In some embodiments, all of the plurality of memory channels 204 of the memory device 240 corresponds to a single queue 216 of memory access requests. Each memory access request is optionally received internally from the memory device 240 to manage the respective memory channel 204 or externally from the host device 220 to write or read data stored in the respective channel 204. Specifically, each memory access request includes one of: a system write request that is received from the memory device 240 to write to the respective memory channel 204, a system read request that is received from the memory device 240 to read from the respective memory channel 204, a host write request that originates from the host device 220 to write to the respective memory channel 204, and a host read request that is received from the host device 220 to read from the respective memory channel 204. It is noted that system read requests (also called background read requests or non-host read requests) and system write requests are dispatched by a memory controller to implement internal memory management functions including, but are not limited to, garbage collection, wear levelling, read disturb mitigation, memory snapshot capturing, memory mirroring, caching, and memory sparing.

In some embodiments, in addition to the channel controllers 214, the controller 202 further includes a local memory processor 218, a host interface controller 222, an SRAM buffer 224, and a DRAM controller 226. The local memory processor 218 accesses the plurality of memory channels 204 based on the one or more queues 216 of memory access requests. In some embodiments, the local memory processor 218 writes into and read from the plurality of memory channels 204 on a memory block basis. Data of one or more memory blocks are written into, or read from, the plurality of channels jointly. No data in the same memory block is written concurrently via more than one operation. Each memory block optionally corresponds to one or more memory pages. In an example, each memory block to be written or read jointly in the plurality of memory channels 204 has a size of 16 KB (e.g., one memory page). In another example, each memory block to be written or read jointly in the plurality of memory channels 204 has a size of 64 KB (e.g., four memory pages). In some embodiments, each page has 16 KB user data and 2 KB metadata. Additionally, a number of memory blocks to be accessed jointly and a size of each memory block are configurable for each of the system read, host read, system write, and host write operations.

In some embodiments, the local memory processor 218 stores data to be written into, or read from, each memory block in the plurality of memory channels 204 in an SRAM buffer 224 of the controller 202. Alternatively, in some embodiments, the local memory processor 218 stores data to be written into, or read from, each memory block in the plurality of memory channels 204 in a DRAM buffer 228A that is included in memory device 200, e.g., by way of the DRAM controller 226. Alternatively, in some embodiments, the local memory processor 218 stores data to be written into, or read from, each memory block in the plurality of memory channels 204 in a DRAM buffer 228B that is main memory used by the processor module 102 (FIG. 1). The local memory processor 218 of the controller 202 accesses the DRAM buffer 228B via the host interface controller 222.

In some embodiments, data in the plurality of memory channels 204 is grouped into coding blocks, and each coding block is called a codeword. For example, each codeword includes n bits among which k bits correspond to user data and (n-k) corresponds to integrity data of the user data, where k and n are positive integers. In some embodiments, the memory device 200 includes an integrity engine 230 (e.g., an LDPC engine) and registers 232 including a plurality of registers or SRAM cells or flip-flops and coupled to the integrity engine 230. The integrity engine 230 is coupled to the memory channels 204 via the channel controllers 214 and SRAM buffer 224. Specifically, in some embodiments, the integrity engine 230 has data path connections to the SRAM buffer 224, which is further connected to the channel controllers 214 via data paths that are controlled by the local memory processor 218. The integrity engine 230 is configured to verify data integrity for each coding block of the memory channels 204.

In some embodiments of this application, the memory controller 202 is coupled to a local controller 280 disposed within a memory package, a memory die 206, or a memory plane 208. A memory system 200 includes a plurality of memory packages. In at least a subset of memory packages, each respective memory package includes a local controller 280 for monitoring and reporting validity conditions of its pages. The memory controller 202 or local controller 280 is configured to obtain an inquiry for a validity condition of a page 210 of the memory device. The page 210 includes a plurality of memory cells that store two consecutive data items and correspond to two nominal threshold voltages. In response to the inquiry, the controller 202 or 280 selects a first readout voltage and a second readout voltage between the two nominal threshold voltages, and applies the first readout voltage and the second readout voltage to read the plurality of memory cells and generate first readout data and second readout data, respectively. An error rate of the page 210 is determined based on the first readout data and the second readout data, and further used to determine whether an error correction process or a background data refresh need to be implemented on the page in different situations.

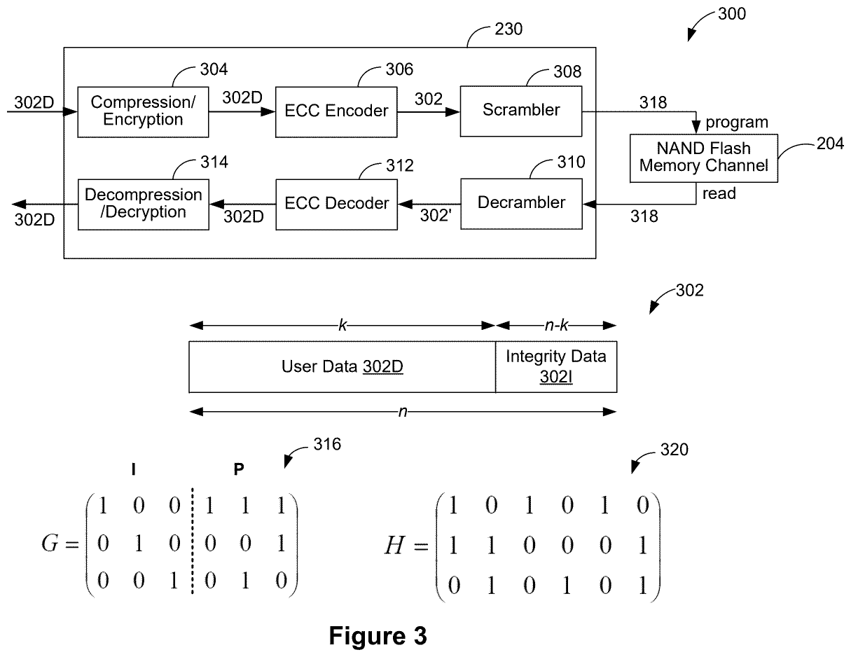

FIG. 3 is a block diagram of an example integrity check system 300 of a memory system 200 for processing a codeword 302, in accordance with some embodiments. The integrity check system 300 includes a plurality of memory channels 204, an integrity engine 230 (e.g., an LDPC engine), and a registers 232. Data stored in memory channels 204 of the memory system 200 (FIG. 2) is grouped into coding blocks, and each coding block is called a codeword 302. Each codeword 302 further includes n data bits among which k data bits are user data 302D and (n−k) data bits are integrity data 302I of the user data 302D, where k and n are positive integers. The integrity check system 300 is configured to verify data integrity for each codeword 302 of the memory channels 204.

In some embodiments, the integrity engine 230 further includes one or more of: a compression module 304, an error correction code (ECC) encoder 306, a scrambler 308, a descrambler 310, an ECC decoder 312, and a decompression module 314. The compression module 304 obtains user data 302D and processes (e.g., compresses, encrypts) the user data 302D. The ECC encoder 306 obtains the user data 302D that is optionally processed by the compression module 304, and applies a parity data generation matrix G (316) on the user data 302D to encode the codeword 302. The matrix G (316) has k rows and n columns. A systematic form of the matrix G includes an identify matrix I configured to preserve the user data 302D within the codeword 302 and a parity matrix P configured to generate the integrity data 302I from the user data 302D. In some embodiments, the matrix G (316) is not unique and includes a set of basis vectors for a vector space of valid codewords 302. The scrambler 308 obtains the codeword 302 including n data bits and converts the n data bits to a scrambled codeword 318 having a seemingly random output string of n data bits. The scrambled codeword 318 is stored in the memory channels 204 of the memory system 200.

During decoding, the scrambled codeword 318′ is extracted from the memory channel 204 of the memory system 200. The descrambler 310 recovers a codeword 302′ from the extracted codeword 318′, and the ECC decoder 312 verifies whether the recovered codeword 302′ is valid and corrects erroneous bits in the recovered codeword 302, thereby providing the valid codeword 302 including the valid user data 302D. In some embodiments, the decompression module 314 obtains the user data 302D and processes (e.g., decompresses, decrypts) the user data 302D. In some embodiments, for integrity check, the ECC decoder 312 multiplies a parity-check matrix H (320) with the recovered codeword 302′ to generate a syndrome vector S. The parity check matrix H (320) includes n-k rows corresponding to n k parity check equations and n columns corresponding to n codeword bits. A relationship of the recovered codeword 302′ and the syndrome vector s is represented as follows:

S=yH^{T} (1)

where y is the recovered codeword 302′. In some embodiments, in accordance with a determination that the syndrome s is equal to 0, the ECC decoder 312 determines that all parity-check equations associated with the parity-check matrix H are satisfied and that the recovered codeword 302′ is valid. Conversely, in accordance with a determination that the syndrome is not equal to 0, the ECC decoder 312 determines that at least a predefined number (e.g., one, two) parity check equation associated with the parity-check matrix H is not satisfied and that the recovered codeword 302′ is not valid. Alternatively, in some embodiments, the ECC decoder 312 operates to solve the following equation:

S=eHT (2)

where e is an error vector. The syndrome vector s is a combination of the error vector e and a valid codeword 302. Given that the syndrome vector s and the parity check matrix H are known, the ECC decoder 312 solves equation (2) to obtain the error vector e and identify the erroneous bits in the recovered codeword 302′.

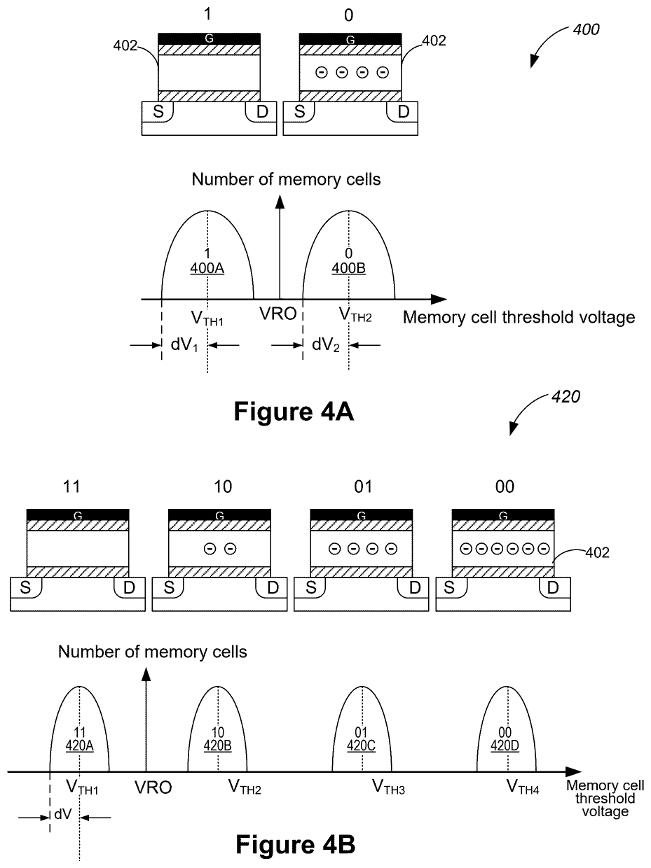

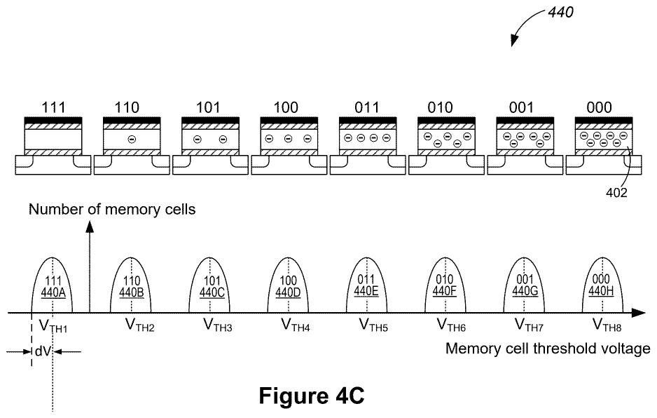

FIG. 4A illustrates an example memory cell threshold voltage probability distribution 400 of an SLC memory cell, in accordance with some embodiments. The SLC memory cell has a gate G, a source S, and a drain D. Either “1” or “0” is stored in each SLC memory cell in accordance with a relationship between a current I_{G} flowing between the source S and the drain D and a gate voltage V_{G} applied on the gate of the SLC memory cell. The higher the gate voltage (V_{G}) is, the easier it is for the current I_{G} to flow. The gate voltage V_{G} has a threshold voltage V_{TH} for which the current I_{G} flows (e.g., is greater than a current threshold I_{GTH}). Either value (e.g., “1” or “0”) stored in the SLC memory cell has a respective threshold voltage V_{TH}. For example, the SLC memory cell storing “1” has a first threshold voltage V_{TH1}, and the SLC memory cell storing “0” has a second threshold voltage V_{TH2}. The first threshold voltage V_{TH1} is lower than the second threshold voltage V_{TH2}.

The threshold voltage of each SLC memory cell depends at least in part on a number of excess electrons existing in a charge storage film 402. In some embodiments, the charge storage film 402 is a floating gate. In some embodiments, the charge storage film 402 is charge trap. In some embodiments, the lower the number of excess electrons in the charge storage film 402 is, the easier it is for the current I_{G} to flow. The first threshold voltage V_{TH1} is low because there are no or few excess electrons in the charge storage film 402, and the second threshold voltage V_{TH2} is higher than the first threshold voltage V_{TH1} because there are more excess electrons in the charge storage film 402. In some embodiments, a memory device 240 has large number of memory cells (e.g., 250-500 GB). Even if all of the memory cells of the memory device 240 store the same data (e.g., “1” or “0”), the memory cells of the memory device 240 differ in their threshold voltages V_{TH1} or V_{TH2}, which have a probability distribution 400. Referring to FIG. 4A, in some embodiments, the memory cells of the memory device 240 have the same probability of storing “1” and “0.” A number of the memory cells has two peaks at the first threshold voltage V_{TH1} corresponding to “1” and the second threshold voltage V_{TH2} corresponding to “0.” A first peak number of memory cells having the first threshold voltage V_{TH1} is substantially equal to a second peak number of memory cells having the second threshold voltage V_{TH2}. The first peak number of memory cells drops below a threshold valley number or to zero within a first deviation voltage dV₁ on both sides of the first threshold voltage V_{TH1}, forming a threshold voltage probability distribution 400A for data “1.” The second peak number of memory cells drops below a threshold valley number or to zero within a second deviation voltage dV₂ on both sides of the second threshold voltage V_{TH2}, forming a threshold voltage probability distribution 400B for data “0.”

During a read operation, the gate voltage V_{G} is set to a readout voltage VRO, which is between the threshold voltage probability distribution 400A for data “1” and the threshold voltage probability distribution 400B for data “0”. For memory cells storing “1,” the first threshold voltages V_{TH1} are lower than the readout voltage VRO, and currents I_{G} flow in the memory cells storing “1.” Conversely, for memory cells storing “0, ” the second threshold voltages V_{TH2} are higher than the readout voltage VRO, and currents I_{G} do not flow or are substantially low (e.g., smaller than the current threshold I_{GTH}) in the memory cells storing “0.”

FIGS. 4B and 4C illustrate example memory cell threshold voltage probability distributions 420 and 440 of an MLC memory cell and an TLC memory cell, in accordance with some embodiments, respectively. Each MLC or TLC memory cell has a gate G, a source S, and a drain D. In accordance with a relationship between a current I_{G} flowing between the gate G and the drain D and a gate voltage V_{G} applied on the gate, each of four data values “11,” “10,” “01, ” and “00” is stored in the MLC memory cell, and each of eight data values “111,” “110,” “101,” “100,” “011,” “010,” “001, ” and “000” is stored in the TLC memory cell. The gate voltage V_{G} has a threshold voltage V_{TH} for which the current I_{G} flows (e.g., is greater than a current threshold I_{GTH}). Each value stored in the respective memory cell has a respective threshold voltage V_{TH}. For example, the MLC memory cell storing “11,” “10,” “01, ” or “00” has a threshold voltage V_{TH1}, V_{TH2}, V_{TH3}, or V_{TH4}, respectively. The TLC memory cell storing “111,” “110,” “101,” “100,” “011,” “010,” “001, ” and “000” has a threshold voltage V_{TH1}, V_{TH2}, V_{TH3}, V_{TH4}, V_{TH5}, V_{TH6}, V_{TH7}, or V_{TH8}, respectively.

The threshold voltage of each memory cell depends at least in part on a number of excess electrons existing in a charge storage film 402. In some embodiments, the lower the number of excess electrons in the charge storage film 402 is, the lower the threshold voltage is and the easier it is for the current I_{G} to flow. In some embodiments, even if all of the MLC or TLC memory cells of the memory device 240 store the same data, these memory cells of the memory device 240 differ in the numbers of excess electrons in the charge storage films 402 and their associated threshold voltages, which have a probability distribution 420 or 440. Referring to FIG. 4B, in some embodiments, the memory cells of the memory device 240 have the same probability of storing “11,” “10,” “01, ” and “00.” A number of the memory cells has four peaks at the threshold voltages V_{TH1}, V_{TH2}, V_{TH3}, and V_{TH4}, corresponding to “11,” “10,” “01, ” and “00, ” respectively. The four peak numbers of memory cells having the threshold voltages V_{TH1}, V_{TH2}, V_{TH3}, and V_{TH4} are substantially equal to one another. Each peak number of memory cells drops below a threshold valley number or to zero within a respective deviation voltage dV on both sides of the respective threshold voltage, forming a threshold voltage probability distribution 420A, 420B, 420C, or 420D.

Referring to FIG. 4C, in some embodiments, the memory cells of the memory device 240 have the same probability of storing “111,” “110,” “101,” “100,” “011,” “010,” “001, ” and “000.” A number of the memory cells has eight peaks at the threshold voltages V_{TH1}, V_{TH2}, V_{TH3}, V_{TH4}, V_{TH5}, V_{TH6}, V_{TH7}, and V_{TH8} corresponding to “111,” “110,” “101,” “100,” “011,” “010,” “001, ” and “000,” respectively. The eight peak numbers of memory cells having the threshold voltages V_{TH1} to V_{TH8} are substantially equal to one another. Each peak number of memory cells drops below a threshold valley number or to zero within a respective deviation voltage dV on both sides of the respective threshold voltage, forming a threshold voltage probability distribution 440A, 440B, 440C, 440D, 440E, 440F, 440G, or 440H.

Referring to FIGS. 4B and 4C, during a read operation, the gate voltage V_{G} is set to a readout voltage VRO, which is between two threshold voltage probability distributions (e.g., 420A for a first data “11” and 420B for a second data “10,” 440A for a first data “111” and 440B for a second data “110”). The threshold voltages V_{TH1} of the memory cells storing the first data are lower than the readout voltage VRO, and their associated currents I_{G} flow. Conversely, the threshold voltages V_{THs} of the memory cells storing the second data are higher than the readout voltage VRO, and their associated currents I_{G} do not flow or are substantially low (e.g., smaller than the current threshold I_{GTH}).

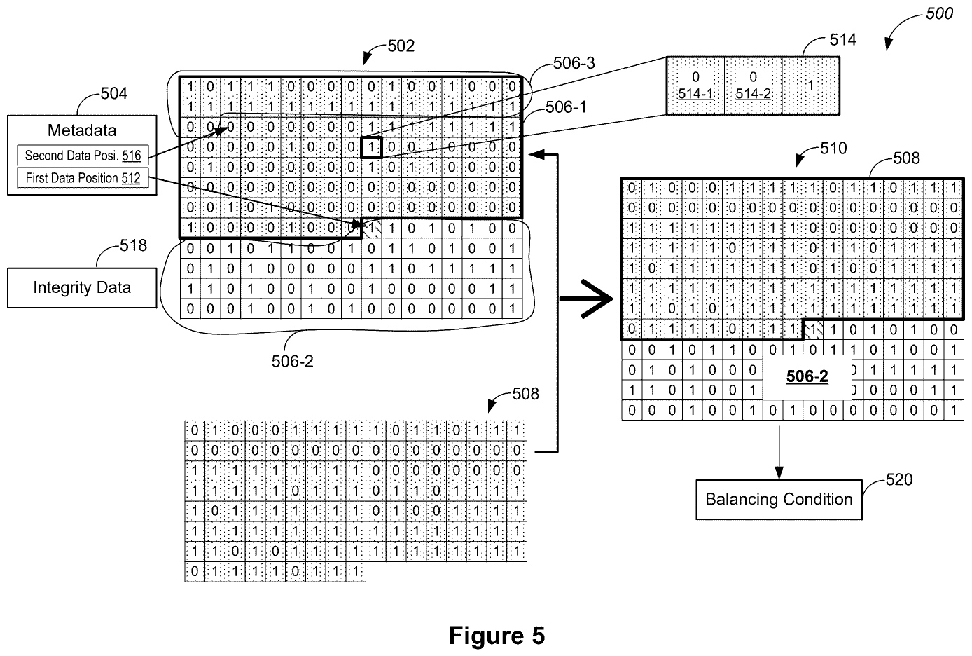

FIG. 5 is an example memory block 500 storing a structured data block 502 in which data bits are flipped for coding balancing, in accordance with some embodiments. A memory device 240 includes a non-volatile memory 280 (e.g., having a plurality of memory channels 204). The non-volatile memory 280 includes a memory block 500. The structured data block 502 and metadata 504 need to be stored on the memory block of the non-volatile memory 280. The structured data block 502 includes a plurality of data items. The memory device 240 identifies a first subset of data items 506-1 among the plurality of data items. The plurality of data items further include a second subset of data items 506-2. The memory device 240 flips the first subset of data items 506-1 to generate a set of flipped data items 508, and replaces the first subset of data items 506-1 of the structured data block 502 with the set of flipped data items 508 to generate a target data block 510, such that the data items 508 and 506-2 of the target data block 510 satisfy a predefined balancing condition 520. After the structured data block 502 is converted to the target data block 510 based on the balancing condition 520, the target data block 510 is stored in the non-volatile memory 280 with the metadata 504 associated with the structured data block 502. By these means, the target data block 510 is balanced, allowing the number of bits in each data level to be predetermined and predictable, independently of the metadata 504 and parity bits.

In some embodiments, each of the second subset of data items 506-2 is distinct from the first subset of data items 506-1, and the second subset of data items 506-2 is complementary to the first subset of data items 506-1 in the structured data block 502. In some embodiments, the first subset of data items 506-1 includes more than one set of successively-arranged data items 506-1, which is distributed in the structured data block 502.

In some embodiments, the metadata 504 includes location information identifying the first subset of data items 506-1 and the second subset of data items 506-2. The memory device 240 determines a first data position 512 that separates the first subset of data items 506-1 and the second subset of data items 506-2 in the structured data block 502. The first subset of data items 506-1 is arranged in the structured data block before the first data position 512, and the second subset of data items starts from the first data position 512. Alternatively, in some embodiments not shown, the second subset of data items 506-2 is arranged in the structured data block 502 before the first data position 512, and the first subset of data items starts from the first data position 512. In some embodiments not shown, the first data position 512 corresponds to a data item included in the first subset of data items 506-1. In some embodiments not shown, the first data position 512 points to a location separating two data items that belong to the first subset of data items 506-1 and the second subset of data items 506-2, respectively. Alternatively, in some embodiments, the first data position 512 includes a plurality of locations identifying a plurality of data item sets of the subset of data items 506-1 or 506-2. The first subset of data items 506-1 may include more than one data item set that is distributed in the structured data block 502.

In some embodiments, the first subset of data items 506-1 are successively arranged in the structured data block 502. Further, in some embodiments, each memory cell stores a single bit, and each data item 506-1 includes a single data bit. The single bit of each of the first subset of data items 506-1 is flipped to generate the set of flipped data items 508. Alternatively, in some embodiments, each of the first subset of data items 506-1 includes a plurality of bits (e.g., 2, 3, 4, or 5 bits). Each and every bit 514 of the first subset of data items 506-1 is flipped to generate the set of flipped data items 508. In an example, the non-volatile memory 280 includes a TLC NAND flash memory, and each data item 506-1 includes 3 data bits, which are flipped to generate the set of flipped data items 508. If a data bit 514 is “0,” the data bit 514 is flipped to “1.” If a data bit 514 is “1,” the data bit 514 is flipped to “0.” An example 3b data item of “001” is flipped to “110.”

In some embodiments, each memory cell stores a plurality of bits (e.g., 2, 3, 4, or 5 bits), and each data item 506-1 or 506-2 includes a plurality of data bits 514 (e.g., a respective first data bit 514-1 and a respective second data bit 514-2). For each of the first subset of data items 506-1, at least one of the plurality of data bits 514 is flipped. Further, in some embodiments, based on the metadata 504, the memory device 240 determines a second data position 516 within the first subset of data items 506-1 in the structured data block 502. A third subset of data items 506-3 is arranged in the first subset of data items 506-1 based on the second data position 516. For example, the third subset of data items 506-3 includes data items located in the first subset of data items 506-1 before the second data position 516. The respective first data bit 514-1 of each of the first subset of data items 506-1 is flipped, and the respective second data bit 514-2 of each of the third subset of data item 506-3 is flipped. In other words, only the third subset of data items 506-3 has both the first data bit 514-1 and the respective second data bit 514-2 flipped. A remainder of the first subset of data items 506-1 has the first data bit 514-1 flipped.

In some embodiments, the target data block 510 is stored with integrity data 518 in the memory block 500. The memory device 240 extracts integrity data 518 associated with the data block 502 or 510 jointly with the target data block 510 and the metadata 504. The memory device 240 verifies a validity of the data block 502 or 510 and the metadata 504 based on the integrity data 518. Further, in some embodiments, the memory device 240 corrects one or more bit errors in the data block 502 or 510 or the metadata 504.

Some implementations of this application are directed to balancing data bits stored in a memory block. A memory controller 202 transforms input user data into a balanced code (e.g., the target data block 510) with some additional metadata 504 or integrity data 518 (e.g., parity bits), while the metadata 504 and integrity data 518 may not be balanced. The balanced target data block 510, metadata 504, and integrity data 518 are written to the memory block 500 of the non-volatile memory 500 jointly. In some embodiments, the memory controller 202 reads the balanced target data block 510, metadata 504, and integrity data 518 from the memory block 500 of the non-volatile memory 500 into a buffer 224 or 228A (FIG. 2). In some embodiments, the memory controller 202 counts the number of bits that are “0” and “1” for each read strobe within a target data block 510 excluding the metadata 504 or integrity data 518. The memory controller 202 may sample a subset set of the balanced target data block 510 for this purpose. If the number of bits for “1” or “0” is close to an expected number (e.g., M_{T}, N_{T}), the error rate is low, and the memory controller 202 continues to read the target data block 510 across the memory block 500. If a difference of the number of bits for “1” or “0” and the expected number (e.g., M_{T}, N_{T}) is greater than a bit limit, the memory controller 202 may adjust one or more read reference voltages associated with different bits 514 and read the target data block 510 using adjusted the one or more read reference voltages. In some embodiments, the memory device 240 applies a soft read with different read strobe signals corresponding to different read reference options, and select the read strobe signal providing the balanced target data block 510 (e.g., satisfying the balancing condition 520).

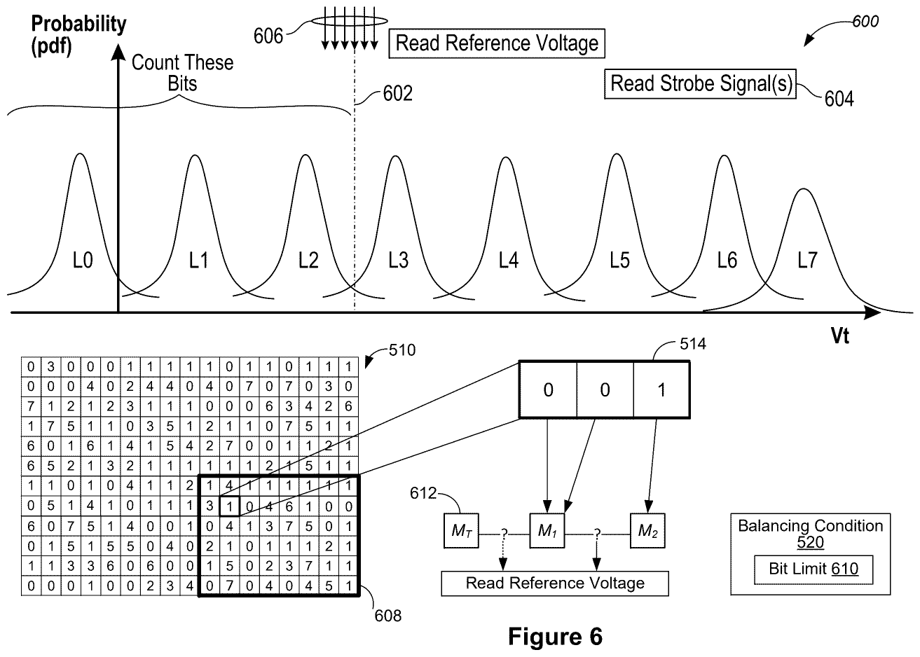

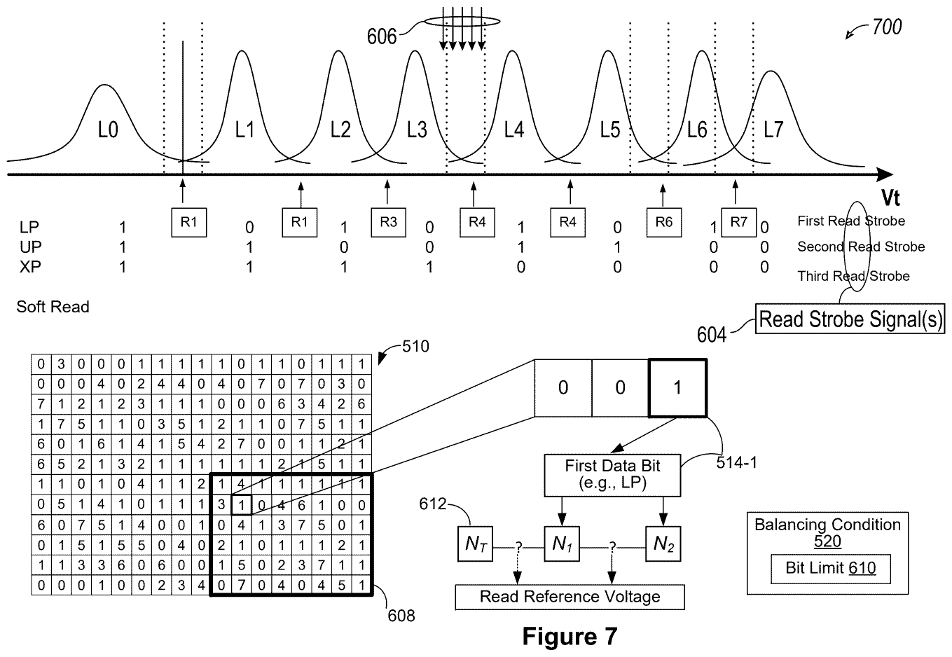

More specifically, in some embodiments, a memory device 240 extracts at least a subset of the target data block 510 from the non-volatile memory 280, and determines whether the target data block 510 satisfies the balancing condition 520. In accordance with a determination that the target data block 510 does not satisfy the balancing condition 520, the memory device 240 adjusts a read reference voltage and applies the adjusted read reference voltage to read the target data block 510. More details on adjustment of the read reference voltage are discussed below with reference to FIGS. 6 and 7.

FIG. 6 is a flow diagram of an example process 600 of moving a read reference voltage 602 of a memory block 500, in accordance with some embodiments. In some embodiments, each memory cell of the memory block 500 is configured to store one or more data bits (e.g., a single data bit in a SLC memory cell, 3 data bits in a TLC memory cell). During a read operation, the memory controller 202 obtains a read strobe signal 604 for reading the target data block 510. In response to the read strobe signal 604, the memory controller 202 determines whether the target data block 510 satisfies the balancing condition 520, e.g., based on a sample set of data items 608. In accordance with a determination that the target data block 510 does not satisfy the balancing condition 520, the memory controller 202 adjusts a read reference voltage 602 to make the target data block 510 satisfy the balancing condition 520 (e.g., associated with a combination of all data bits 514, associated with one of the data bits 514), and applies the read reference voltage 602 that is adjusted to read the target data block 510. The target data block 510 is then converted to recover the structured data block 502 based on the metadata 504 (e.g., a flip bit position). In some embodiments, more than two read reference voltages 602 are adjusted to balance the target data block 510.

A read reference voltage 602 in an SSD refers to a specific voltage level used by a memory controller 202 to read data from the memory cells, acting as a threshold to determine whether a memory cell is storing one of two consecutive data levels (e.g., “0” and “1” in a single level cell memory, “001” and “010” in a TLC memory) by comparing its read voltage against the read reference voltage. In some embodiments, the memory block 500 includes a plurality of TLC memory cells, and each memory cell of the memory block is configured to store a plurality of data bits 514 (e.g., 3 data bits). The read reference voltage 602 is used to read two successive data levels (e.g., “010” (L2) and “011” (L3)).

In some embodiments, each memory cell of the memory block 500 is configured to store a plurality of data bits 514 (e.g., 3 data bits of a TLC memory cell). The memory device 240 applies a read strobe signal 604 to initial a memory read operation. In response to the read strobe signal 604, the memory device 240 applies a plurality of read reference options 606 corresponding to every two successive data levels (e.g., L2 and L3). The memory device 240 identifies a sample set of data items 608 and determines that the sample set of data items 608 includes a respective number (M₁) of data bits having a first bit value (e.g., “1” or “0”) in total. The memory device 240 selects one of the plurality of read reference options 606 satisfying a balancing condition 520 (e.g., requiring that the respective number (M₁) of the selected read reference option is closest to a target bit number 612 (M_{T}) among the plurality of read reference options 606). The one of the plurality of read reference options 606 is applied as the adjusted read reference voltage 602 to extract the target data block 510.

Alternatively, in some embodiments, the balancing condition 520 requires that a difference of the respective number (M₁) corresponding to the first bit value (e.g., “1”) and another number (M₂) corresponding to a distinct second bit value (e.g., “0”) fall below a bit limit 610. For example, the bit limit 610 is 1, and the numbers M1 and M2 have to be equal, e.g., perfectly balanced. In another example, for a data block size of 4 KB, the bit limit 610 is 10 bits, and the target data block 510 is balanced when numbers of bits having values of “1” and “0” differ by less than 10. In some embodiments, the balancing condition 520 requires that a difference of the respective number (M₁) corresponding to the first bit value (e.g., “1”) and the target bit number 612 (M_{T}) fall below a bit limit 610. For example, the target bit number 612 (M_{T}) differs from a half of a total number of bits the target data block 510 has by less than 1%.

In some embodiments, the sample set of data items 608 are read after a set of read reference voltages 602 is applied, and each read reference voltage 602 corresponds to one or more respective read reference options 606. For example, the read reference voltage between L2 and L3 corresponds to one or more options 606, and the read reference voltage between L6 and L7 corresponds to one or more distinct options not shown in FIG. 6. The set of read reference voltages 602 may need to be dynamically or iteratively combined to balance the plurality of data bits 514 of the structured data block 502 in accordance with the balancing condition 520.

FIG. 7 is a flow diagram of another example process of moving a read reference voltage 602 of a memory block 500, in accordance with some embodiments. In some embodiments, each memory cell stores a plurality of bits 514, and the memory block 500 is balanced for each of the plurality of bits 514, e.g., by flipping respective data bits based on different bit positions as described in FIG. 5. A read strobe signal 604 is applied. In response to the read strobe signal 604, the memory device 240 (specifically, the memory controller 202) extracts a first data bit 514-1 of the plurality of data bits 514 of each memory cell of a subset of the memory block 500, and the subset of the memory block 500 stores a sample set of data items 608 of the plurality of data items of the target data block 510. In some situations, the sample set of data items 608 is less than all data items stored in the memory block 500 of the target data block 510, thereby expediting estimation of a data balancing condition of the memory block 500. In some situations, the sample set of data items 608 includes all data items of the target data block 510 stored in the memory block 500, thereby estimating the data balancing condition accurately.

In some embodiments, the memory device 240 applies a read reference voltage 602 to read the sample set of data items 608, and determines that the sample set of data items 608 includes a first number (N₁) of data items having a first bit value for the first data bit 514-1. The memory device 240 adjusts the read reference voltage until the first number (N₁) satisfies a balancing condition 520, and applies the adjusted read reference voltage to extract the first data bit 514-1 of the plurality of data bits 514 of the plurality of data items of the target data block 510.

In some embodiments, the memory device 240 determines that the sample set of data items 608 include a first number (N₁) of data items having a first bit value (e.g., “1”) for the first data bit 514-1 (e.g., corresponding to a subpage XP), and dynamically adjusts a read reference voltage 602 based on the first number (N₁). The adjusted read reference voltage 602 is applied to extract the structured data block 502 and the metadata 504 from the memory block 500. Further, in some embodiments, the memory device 240 determines that the sample set of data items 608 include a second number (N₂) of data items having a second bit value (e.g., “0”) for the first data bit 514-1, and the read reference voltage is adjusted to control a difference between the first number (N₁) and the second number (N₂) below a predefined bit limit 610. In other words, the balancing condition 520 requires that the difference between the first number (N₁) and the second number (N₂) below the predefined bit limit 610. Alternatively, in some embodiments, the first number (N₁) is compared with a target bit number (NT), and the read reference voltage 602 is adjusted to control a difference between the first number (N₁) and the target bit number (N_{T}) below a predefined bit limit 610.

In some embodiments, each page 210 of memory cells has a plurality of subpages (e.g., XP, UP, and LP), and each subpage corresponds to a respective bit of the plurality of bits representing the set of consecutive data items. For example, each MLC-based page 210 has two subpages, and each subpage corresponds to one of two bits representing a set of four consecutive data items (e.g., in FIG. 4B). Each TLC-based page 210 has three subpages, and each subpage 702 corresponds to one of three bits representing a set of eight consecutive data items. Each QLC-or PLC-based page 210 has four or five subpages, and each subpage corresponds to one of four or five bits representing a set of sixteen or thirty-two consecutive data items, respectively. More specifically, for the TLC-based page 210, the three subpages includes an extra page XP, an upper page UP, and a lower page LP that correspond to a most significant bit, a middle bit, and a least significant bit representing the set of eight consecutive data items. In some embodiments, the balancing condition 520 is applied to all bits on all memory subpages jointly.

In some embodiments, the balancing condition 520 is applied to the data bits on each memory subpage (e.g., on XP, UP, or LP), e.g., a subpage corresponding to a data bit 514-1 and a read strobe signal 604. For each of the subpages XP, UP, or LP, different read reference voltages are applied and adjusted (if needed) to satisfy the balancing condition. For example, for the subpage LP corresponding to the least significant bit 514-1, all read reference voltages corresponding to valleys R1-R7 are applied to read the first number (N₁) of data bits having a first value (e.g., “1”), and a subset of all of the read reference voltages are adjusted to balance the bit numbers N1 and N2. For the subpage XP, the read reference voltage corresponding to valley R4 is applied to read the first number (N₁) of data bits having a first value (e.g., “1”), and adjusted to balance the associated bit numbers N1 and N2. For the subpage UP, the read reference voltage corresponding to valleys R2, R4, and R6 are applied to read the first number (N₁) of data bits having a first value (e.g., “1”), and a subset or all of these read reference voltages are adjusted to balance the associated bit numbers N1 and N2.

Alternatively, in some embodiments (e.g., associated with FIG. 6), the balancing condition 520 is applied to the data bits on a memory page 210 including a plurality of data bits 514. Different read reference voltages are applied, and at least one read reference voltage 602 is adjusted to satisfy the balancing condition 520 for the plurality of data bits 514. For example, the first number (N₁) of data bits is determined for all three data bits 514 of the sample set of data items 608, and at least one read reference voltage 602 corresponding to at least one of valleys R1-R7 may be adjusted to balance the associated bit numbers N1 and N2.

In some embodiments, a balanced data block includes substantially the same numbers of 0s and 1s. In an example associated with a TLC NAND flash memory, the balanced data block may include 50% 0s and 50% 1s, and may not include 12.5% for each of the eight 3-bit values (e.g., “000,” “001,” “010, ” . . . and “111”). Further, in some embodiments, a variance among the eight 3-bit values is substantially low.

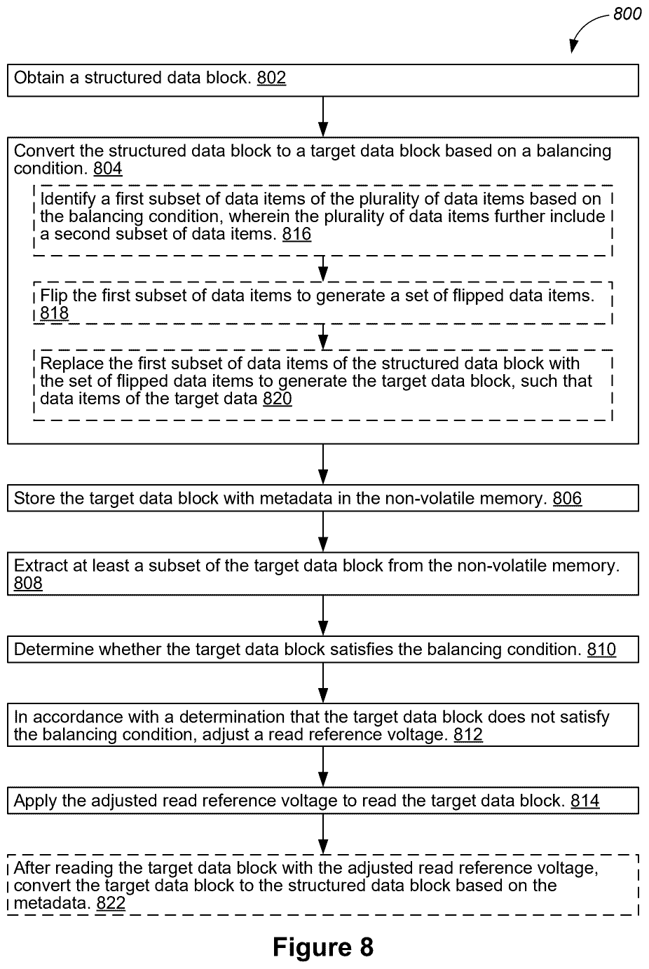

FIG. 8 is a flow diagram of an example method for balancing codes in a memory device, in accordance with some embodiments. A memory device including a non-volatile memory. The memory device obtains (operation 802) a structured data block and converts (operation 804) the structured data block to a target data block based on a balancing condition. The memory device stores (operation 806) the target data block with metadata in the non-volatile memory, extracts (operation 808) at least a subset of the target data block from the non-volatile memory, and determines (operation 810) whether the target data block satisfies the balancing condition. In accordance with a determination that the target data block does not satisfy the balancing condition, the memory device 240 adjusts (operation 812) a read reference voltage and applies (operation 814) the adjusted read reference voltage to read the target data block.

In some embodiments, the structured data block includes a plurality of data items. The memory device converts the structured data block by identifying (operation 816) a first subset of data items of the plurality of data items based on the balancing condition, flipping (operation 818) the first subset of data items to generate a set of flipped data items, and replacing (operation 820) the first subset of data items of the structured data block with the set of flipped data items to generate the target data block, such that data items of the target data block satisfy the balancing condition. Further, in some embodiments, each and every bit of the first subset of data items is flipped to generate the set of flipped data items.

In some embodiments, the memory device determines a first data position that separates the first subset of data items and the second subset of data items in the structured data block, and generates the metadata indicating the first data position. The first subset of data items is arranged in the structured data block before the first data position, and the second subset of data items starts from the first data position. Additionally, in some embodiments, each of the plurality of data items includes a respective first data bit and a respective second data bit. The memory device determines a second data position within the first subset of data items in the structured data block. A third subset of data items is arranged in the first subset of data items based on the second data position, and the metadata further indicates the second data position. The memory device flips the respective first data bit of each of the first subset of data items and the respective second data bit of each of the third subset of data item.

In some embodiments, each of the second subset of data items is distinct from the first subset of data items, and the second subset of data items is complementary to the first subset of data items in the structured data block.

In some embodiments, the memory device generates integrity data based on the set of flipped data items and the second subset of data items, and stores the integrity data with the set of flipped data items, the second subset of data items, and the metadata in a memory block of the non-volatile memory.

In some embodiments, the memory device generates integrity data associated with the structured data block and stores the integrity data with the target data block and the metadata in a memory block of the non-volatile memory.

In some embodiments, the subset of the target data block includes a sample set of data items, and the sample set of data items includes less than all data items included in the target data block.

In some embodiments, the subset of the target data block includes a sample set of data items, and the sample set of data items includes all data items included in the target data block.

In some embodiments, the subset of the target data block including a sample set of data items. The memory device applies the read reference voltage to read a sample set of data items, and determines that the sample set of data items includes a first number (N₁) of data items having a first bit value for a first data bit. The read reference voltage is adjusted until the first number (N₁) satisfies the balancing condition. Further, in some embodiments, the memory device determines that the sample set of data items include a second number (N₂) of data items having a second bit value for the first data bit. Based on the balancing condition, the read reference voltage is adjusted to control a difference between the first number (N₁) and the second number (N₂) below a predefined bit limit. In some embodiments, the memory device 240 compares the first number (N₁) with a target bit number. Based on the balancing condition, the read reference voltage is adjusted to control a difference between the first number (N₁) and a target bit number below a predefined bit limit.

In some embodiments, each data item of the target data block includes a plurality of data bits stored in a respective memory cell. The memory device adjusts the read reference voltage by applying a plurality of read reference options corresponding to every two successive data levels of data items of the target data block; identifying a sample set of data items included in the subset of the target data block; for each of the plurality of read reference options, determining that the sample set of data items includes a respective number (M₁) of data bits having a first bit value in total; and selecting a subset of the plurality of read reference options based on the respective numbers (M₁)of data bits. The subset of the plurality of read reference options is applied the adjusted read reference voltage to extract the target data block. Further, in some embodiments, based on the balancing condition, the respective number (M₁) of the adjusted read reference voltage is the closest to a target bit number among the respective numbers (M₁) corresponding to the plurality of read reference options.

In some embodiments, the read reference voltage is adjusted to make the target data block satisfy the balancing condition. After reading the target data block with the adjusted read reference voltage, the memory device converts (operation 822) the target data block to the structured data block based on the metadata.

In some embodiments, the target data block includes a plurality of subpages corresponding to a plurality of data bits of each data item stored by the target data block. For each subpage corresponding to a respective one of the plurality of data bits, the target data block has a first number of bits having a first bit value and a second number of bits having a second bit value that is different from the first bit value. The balancing condition is applied on each subpage, and in accordance with the balancing condition of each subpage, in accordance with the balancing condition, the first number and the second number are equal.

In some embodiments, the target data block includes a plurality of subpages corresponding to a plurality of data bits of each data item stored by the target data block. For each subpage corresponding to a respective one of the plurality of data bits, the target data block has a first number of bits having a first bit value and a second number of bits having a second bit value that is different from the first bit value. The balancing condition is applied on each subpage, and in accordance with the balancing condition of each subpage, a difference of the first number and the second number is less than a predefined bit limit.

In some embodiments, the target data block includes a plurality of data items, and each of the plurality of data items has a respective single bit and is stored in a respective memory cell of the non-volatile memory.

In some embodiments, the target data block includes a plurality of data items, and each of the plurality of data items has a plurality of data bits and is stored in a respective memory cell of a respective memory block of the non-volatile memory.

In accordance with some embodiments of this application, balanced codes allow the memory controller 202 to see if there are more “0” to “−1” errors or more “1” to −“0” errors. Error correction decoders can make use of this information to correct more bit errors. An SSD can search for an optimal read reference much more quickly, which helps quality of service (QoS) considerably by speeding up an error recovery flow. A comparison of an actual number of bits and an expected number of bits indicates whether to increase or decrease each read reference voltage. In some embodiments, the memory controller 202 performs a multi-dimensional search in parallel when there are multiple read references needed for a memory page read. When counts are read by the memory controller, it can decide on the best read reference voltage for future read commands. By these means, the memory device 240 reduces an input/output bus latency and an error correction decoding latency, identifies an accurate read reference voltage, and enhances a probability of correcting errors.

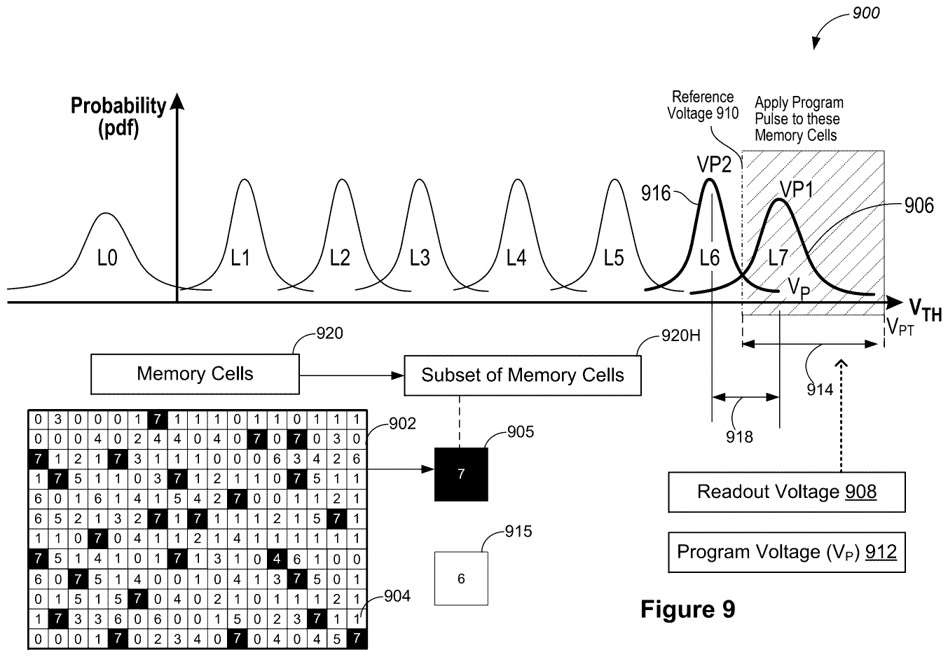

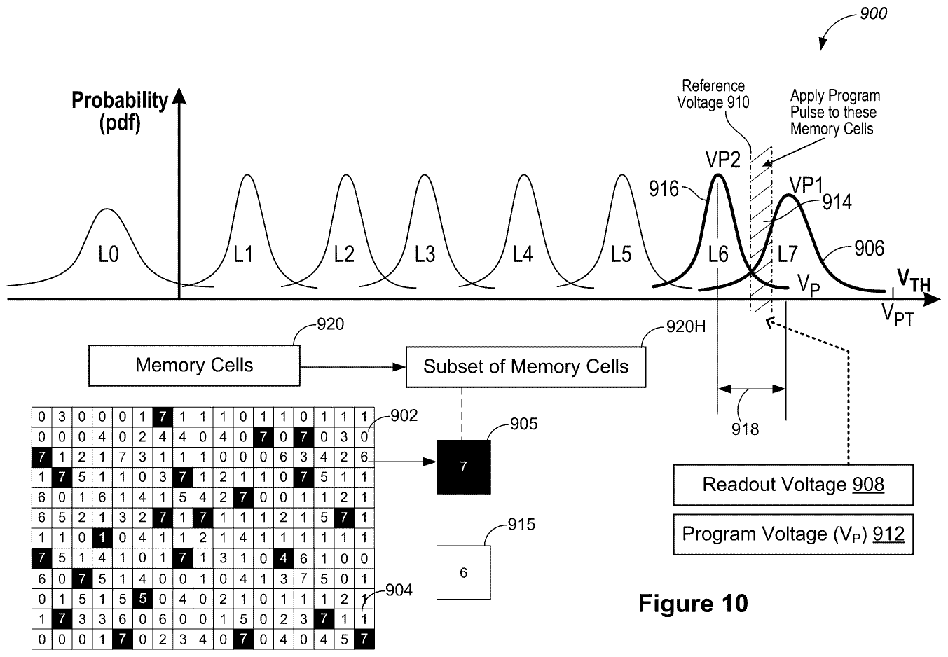

FIGS. 9 and 10 illustrate two example threshold voltage probability distributions 900 for a data block 902 having a plurality of data items 904, in accordance with some embodiments. Each data item 904 is stored in an TLC memory cell, which is used for convenience of reference. Selective background data refresh may be applied to X-level memory cells other than the TLC memory cell, where X is an integer greater than 1.

The TLC memory cell is configured to store one of eight data values including “111,” “110,” “101,” “100,” “011,” “010,” “001, ” and “000.” The TLC memory cell storing “111,” “110,” “101,” “100,” “011,” “010,” “001, ” or “000” has a distinct threshold voltage V_{TH1}, V_{TH2}, V_{TH3}, V_{TH4}, V_{TH5}, V_{TH6}, V_{TH7}, or V_{TH8}, respectively. The threshold voltage of each memory cell depends at least in part on a number of electrons existing in a charge storage film 402. The lower the number of electrons in the charge storage film 402 is, the lower the threshold voltage is and the easier it is for the current I_{G} to flow. In some embodiments, the memory cells of the memory device 240 have distinct numbers of memory cells, and distinct probabilities of, storing “111,” “110,” “101,” “100,” “011,” “010,” “001, ” and “000.” A probability of storing an available value has eight peaks with respect to the threshold voltages V_{TH1}, V_{TH2}, V_{TH3}, V_{TH4}, V_{TH5}, V_{TH6}, V_{TH7}, or V_{TH8} corresponding to “000,” “111,” “110,” “101,” “100,” “011,” “010,” “001, ” or “000, ” respectively, so does a number of memory cells. In some embodiments, each peak probability drops below a threshold valley probability or to zero within a respective deviation voltage dV on both sides of the respective threshold voltage, forming a threshold voltage probability distribution L0, L1, L2, L3, L4, L5, L6, or L7. In some embodiments, eight peak probabilities are substantially equal to one another. In some embodiments, at least two of the eight peak probabilities are not equal to each other. It is noted that, in some embodiments, the threshold voltage probability distributions L0-L7 are not limited to the aforementioned sequence of 3b data items. For example, the threshold voltage probability distributions L0-L7 may be assigned a distinct ordered-sequence of 3b data items (e.g., “111,” “011,” “001,” “101,” “100,” “000,” “010, ” and “110”), in which every two consecutive data items (e.g., “100” and “000” corresponding to distributions L4and L5, respectively) vary by one bit.

Each of the threshold voltage probability distributions L0 to L7 spreads out over a spreading range, e.g., which approximates twice of the respective deviation voltage 2dV. A valley forms between every two immediately adjacent distributions of the threshold voltage probability distributions L0 to L7. In some embodiments, each of the distributions L0-L7 has a relatively wide spreading range (e.g., greater than a threshold range), and the spreading ranges of the two immediately adjacent distributions overlap. In some embodiments, neither of the probability values of the two immediately adjacent distributions drops to the threshold valley probability or to zero on a bottom of their associated valley. For example, in some embodiments, peaks values of threshold voltage probability distributions L3 and L4 drops from their peaks to the bottom of the valley and are equal to each other on the bottom.

In some embodiments, the data block 902 is stored at a non-volatile memory 280 of a memory device 240. The non-volatile memory 280 include a plurality of X-level memory cells 920, and X is equal to an integer number greater than 1. In some embodiments, the memory device 240 includes a multi-level cell (MLC) NAND flash memory chip, and each memory cell of the MLC NAND flash memory chip stores 2 data bits. In an example, each memory cell of a triple-level cell (TLC) NAND flash memory chip stores 3 data bits. In another example, each memory cell of a quad-level cell (QLC) NAND flash memory chip stores 4 data bits. In yet another example, each memory cell of a penta-level cell (PLC) NAND flash memory chip stores 5 data bits. In some embodiments, each memory cell can store any suitable number of data bits.

Each data item 904 is stored in a respective X-level memory cell of the non-volatile memory 280, and has an integer value in a range of [0, 2^{X}−1] inclusively. In other words, an integer value in the range of [0, 2^{X}−1] can be found in a subset of respective memory cells in the non-volatile memory. For examples, for a memory block having TLC memory cells, each memory cell stores any integer value in [0, 7]. In some situations, each and every integer in the range of [0, 7] (e.g., of eight integers) is distributed in the memory block. Alternatively, in some embodiments, each and every integer of a subset of the range of [0, 7] (e.g., of a subset of less than eight integers) is distributed in the memory block.

In some embodiments, a memory device 240 (e.g., an SSD) runs a background data refresh including a full read, an error correction decode, and a write back periodically and on regular intervals to mitigate accumulation of errors due to charge leakage. In some embodiments, the background data refresh is not applied to all memory cells of the memory block storing the data block 902, and instead, applied only to a subset of memory cells which stores the highest data value allowed by an X-level memory cell. For a TLC NAND flash memory, the charge leakage affects the level 7 (L7), which is a program level with the highest threshold voltages (Vth). The background data refresh is selectively applied to a subset of memory cells storing the highest data value (e.g., “7”), i.e., a first value 905.

More specifically, in some implementations, a read operation is applied based on a reference voltage 910 to identify a set of data items 904 having the highest integer value (e.g., “7”), i.e., the first value 905. The set of data items 904 corresponds to a set of X-level memory cells having the highest threshold voltages V_{TH7} distributed according to a curve 906. The curve 906 represents a probability distribution of the threshold voltages V_{TH7} for a subset of memory cells that can be read as storing the highest integer value (e.g., “7”). In some embodiments, the set of data items 904 is refreshed entirely in the background data refresh (e.g., in FIG. 9). Alternatively, in some embodiments, one or more memory cells close to a high end of the curve 906 are excluded from the background data refresh, and less than all of the set of data items 904 is refreshed in the background data refresh (e.g., in FIG. 10). The reference voltage 910 is located on the curve 906, and corresponds to a threshold voltage V_{TH} of the memory cells storing the first value 905.

In some embodiments, the memory device 240 (specifically, the memory controller 202) applies a readout voltage 908 based on a reference voltage 910 to read data of the data block 902 stored in the plurality of X-level memory cells 920 (e.g., TLC memory cells), and the plurality of X-level memory cells 920 are configured to store a plurality of successive integer values (e.g., 0-7). Based on the readout voltage 908, the memory device 240 identifies a subset of memory cells 920H of the plurality of memory cells 920 storing a first value 905 of the plurality of successive integer values. The first value 905 (e.g., “7”) is the largest integer value stored by the plurality of successive integer values (e.g., 0-6). The memory device 240 programs the subset of memory cells 920H to re-write the first value 905 in the subset of memory cells 920H, e.g., using a program voltage 912 (V_{P}) corresponding to a peak of the curve 906 or equal to pass-through voltage V_{PT}.

In some embodiments, the subset of the plurality of memory cells 920H is programmed according to a background refresh rate. After the subset of memory cells 920 is programmed, the memory device 240 aborts programming a remainder of the plurality of memory cells 920 in a corresponding background data refresh. The remainder is complementary to the subset of memory cells 920H.

In some embodiments, the memory device 240 identifies a voltage range 914 based on the reference voltage 902, and applies the readout voltage 908 by increasing the readout voltage 908 in the voltage range 914. While increasing the readout voltage 908 in the voltage range 914, the memory device 240 determines that each of the subset of memory cells 920H has a respective transistor that is switched from an off state to an on state (e.g. that a threshold of each respective memory cell 920H has a threshold voltage V_{TH} in the voltage range 914). Referring to FIG. 9, in some embodiments, the voltage range 914 starts from a valley between threshold voltage distribution curves 906 and 916 of the highest two voltage levels (e.g., “L6” and “L7”) and extends above the highest threshold voltage of all of the plurality of memory cells 920. Referring to FIG. 10, in some embodiments, the voltage range 914 starts from a valley between threshold voltage distribution curves 906 and 916 of the highest two voltage levels (e.g., “L6” and “L7”) and extends to a threshold voltage V_{TH7} corresponding to a peak of the curve 906. F

In some embodiments, the plurality of X-level memory cells 920 have a plurality of peak probabilities at a plurality of feature threshold voltages for storing the plurality of successive integer values (e.g., “0” to “7” in FIGS. 9 and 10). The memory device 240 identifies the reference voltage 910 in a range 918 between two largest feature threshold voltages VP1 and VP2 of the plurality of feature threshold voltages. Each of the subset of memory cells 920H stores the first value 905 has a respective threshold voltage greater than the read reference voltage. Further, in some embodiments, the reference voltage 910 is an average of two largest feature threshold voltages VP1 and VP2 of the plurality of feature threshold voltages.

Alternatively, in some embodiments, when the memory device 240 identifies the reference voltage 910, the memory device 240 determines a first number of memory cells storing the first value 905 with respect to an associated threshold voltage in the range 918, and a second number of memory cells storing a second value 915 (e.g., “6”) with respect to an associated threshold voltage in the range 918. The second value 915 is the largest value among the remainder of the plurality of successive integer values (e.g., 0-7). In accordance with a determination that the first number is equal to the second number at an intermediate threshold voltage, and the memory device 240 sets the read reference voltage based on the intermediate threshold voltage. Stated another way, the reference voltage 910 corresponds to a valley between two curves 906 and 916 corresponding to the first value 905 and the second value 915.

In some embodiments, the reference voltage 910 includes a first reference voltage V_{RR1}, and a second reference voltage V_{RR2} greater than the first reference voltage V_{RR1}, and each of the subset of memory cells 920H storing the first value 905 has a respective threshold voltage greater than the first reference voltage V_{RR1} and less than the second reference voltage V_{RR2}, and is selected and programed in a background data refresh. Additionally, in some embodiments, the second reference voltage V_{RR2}, is equal to a first feature threshold voltage VP1 corresponding to the first value 905 (e.g., a threshold voltage V_{TH7} corresponding to a peak of the curve 906). Alternatively, referring to FIG. 9, in some embodiments, the second reference voltage V_{RR2} is equal to or greater than a pass-through voltage VPT configured to turn on all of the plurality of X-level memory cells 920.

Alternatively, referring to FIG. 10, in some embodiments, the second reference voltage V_{RR2} is lower than a first feature threshold voltage VP1 corresponding to the first value 905 (e.g., a threshold voltage V_{TH7} corresponding to a peak of the curve 906). In some embodiments, for the plurality of X-level memory cells 920, X is equal to 3, and the first value 905 is equal to 7. The memory device 240 is a TCL-based memory flash. The plurality of memory cells 920 includes an overall number of memory cells storing the first value 905 in total. The subset of memory cells 920H that is programmed includes a target number of memory cells, and the target number is less than a half of the overall number.

Under some circumstances, a soft read command checks for memory cells between two reference voltages V_{RR1} and V_{RR2}. Less than all of the set of data items 904 having the highest integer value (e.g., “7”) is identified and refreshed in the background data refresh. No voltage higher than the reference voltage V_{RR2} is applied for the background refresh, which is preferable because fewer memory cells on neighboring word lines are affected by additional program pulses having higher voltage. This chooses memory cells that are below the L7 program verify voltage, so that there is definitely a decrease in the memory cells originally programmed V_{TH7} that needs to be corrected. After identifying the memory cells between two reference voltages V_{RR1} and V_{RR2}, the memory controller 202 sends a program pulse to these memory cells. This operation can be done entirely inside the memory device 240. By these means, the background data refresh is implemented less frequently with a longer background data refresh interval.

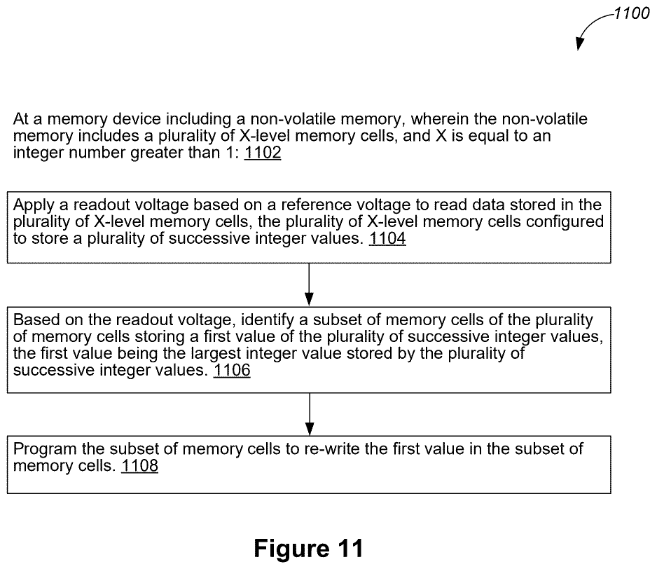

FIG. 11 is a flow diagram of an example method 1100 for refreshing data (e.g., in a background refresh) in a memory device 240, in accordance with some embodiments. The memory device 240 includes (operation 1102) a non-volatile memory, and the non-volatile memory further includes a plurality of X-level memory cells, and X is equal to an integer number greater than 1. In some embodiments, X is equal to 2, 3, 4, or 5. In some embodiments, X is equal to 3, 4, 8, 16, or 32. The memory device applies (operation 1104) a readout voltage based on a reference voltage to read data stored in the plurality of X-level memory cells. The plurality of X-level memory cells are configured to store a plurality of successive integer values. Based on the readout voltage, the memory device identifies (operation 1106) a subset of memory cells of the plurality of memory cells storing a first value of the plurality of successive integer values. The first value is the largest integer value stored by the plurality of successive integer values. The memory device programs (operation 1108) the subset of memory cells to re-write the first value in the subset of memory cells.

In some embodiments, the memory device 240 identifies a voltage range based on the reference voltage. The memory device applying the readout voltage includes increasing the readout voltage in the voltage range. While increasing the readout voltage in the voltage range, the memory device determines that each of the subset of memory cells has a respective transistor that is switched from an off state to an on state.

In some embodiments, the memory device 240 aborts programming a remainder of the plurality of memory cells in a corresponding background data refresh, and the subset of the plurality of memory cells is programmed according to a background refresh rate.

In some embodiments, the plurality of X-level memory cells have a plurality of peak probabilities at a plurality of feature threshold voltages for storing the plurality of successive integer values. The memory device identifies the reference voltage in a range between two largest feature threshold voltages of the plurality of feature threshold voltages, and each of the subset of memory cells storing the first value has a respective threshold voltage greater than the reference voltage.

Further, in some embodiments, when the memory device identifies the reference voltage, the memory device determines a first number of memory cells storing the first value with respect to an associated threshold voltage in the range, and a second number of memory cells storing a second value with respect to an associated threshold voltage in the range. The second value is the second largest value among the plurality of successive integer values. In accordance with a determination that the first number is equal to the second number at an intermediate threshold voltage, the memory device sets the reference voltage based on the intermediate threshold voltage.

In some embodiments, the reference voltage is an average of two largest feature threshold voltages of the plurality of feature threshold voltages. In some embodiments, the reference voltage includes a first reference voltage, and a second reference voltage is greater than the first reference voltage, and each of the subset of the plurality memory cells storing the first value has a respective threshold voltage greater than the first reference voltage and less than the second reference voltage. Additionally, in some embodiments, the second reference voltage is equal to a first feature threshold voltage corresponding to the first value. In some embodiments, the second reference voltage is less than a first feature threshold voltage corresponding to the first value. In some embodiments, the second reference voltage is equal to or greater than a pass-through voltage configured to turn on all of the plurality of X-level memory cells.

In some embodiments, X is equal to 3, and the first value is equal to 7. The memory device is a TCL-based memory flash. The plurality of memory cells includes an overall number of memory cells storing the first value in total. The subset of memory cells that is programmed includes a target number

Memory is also used to store instructions and data associated with the method 800, and includes high-speed random-access memory, such as SRAM, DDR DRAM, or other random access solid state memory devices; and, optionally, includes non-volatile memory, such as one or more magnetic disk storage devices, one or more optical disk storage devices, one or more flash memory devices, or one or more other non-volatile solid state storage devices. The memory, optionally, includes one or more storage devices remotely located from one or more processing units. Memory, or alternatively the non-volatile memory within memory, includes a non-transitory computer readable storage medium. In some embodiments, memory, or the non-transitory computer readable storage medium of memory, stores the programs, modules, and data structures, or a subset or superset for implementing method 800. Alternatively, in some embodiments, the electronic system implements the method 800 at least partially based on an ASIC. The memory system 200 of the electronic system includes an SSD in a data center or a client device.

Each of the above identified elements may be stored in one or more of the previously mentioned memory devices, and corresponds to a set of instructions for performing a function described above. The above identified modules or programs (i.e., sets of instructions) need not be implemented as separate software programs, procedures, modules or data structures, and thus various subsets of these modules may be combined or otherwise re-arranged in various embodiments. In some embodiments, the memory, optionally, stores a subset of the modules and data structures identified above. Furthermore, the memory, optionally, stores additional modules and data structures not described above.

The terminology used in the description of the various described implementations herein is for the purpose of describing particular implementations only and is not intended to be limiting. As used in the description of the various described implementations and the appended claims, the singular forms “a,” “an” and “the” are intended to include the plural forms as well, unless the context clearly indicates otherwise. It will also be understood that the term “and/or” as used herein refers to and encompasses any and all possible combinations of one or more of the associated listed items. It will be further understood that the terms “includes,” “including,” “comprises,” and/or “comprising,” when used in this specification, specify the presence of stated features, integers, steps, operations, elements, and/or components, but do not preclude the presence or addition of one or more other features, integers, steps, operations, elements, components, and/or groups thereof. Additionally, it will be understood that, although the terms “first,” “second,” etc. may be used herein to describe various elements, these elements should not be limited by these terms. These terms are only used to distinguish one element from another.

As used herein, the term “if” is, optionally, construed to mean “when” or “upon” or “in response to determining” or “in response to detecting” or “in accordance with a determination that,” depending on the context. Similarly, the phrase “if it is determined” or “if [a stated condition or event] is detected” is, optionally, construed to mean “upon determining” or “in response to determining” or “upon detecting [the stated condition or event]” or “in response to detecting [the stated condition or event]” or “in accordance with a determination that [a stated condition or event] is detected,” depending on the context.

The foregoing description, for purpose of explanation, has been described with reference to specific embodiments. However, the illustrative discussions above are not intended to be exhaustive or to limit the claims to the precise forms disclosed. Many modifications and variations are possible in view of the above teachings. The embodiments were chosen and described in order to best explain principles of operation and practical applications, to thereby enable others skilled in the art.

Although various drawings illustrate a number of logical stages in a particular order, stages that are not order dependent may be reordered and other stages may be combined or broken out. While some reordering or other groupings are specifically mentioned, others will be obvious to those of ordinary skill in the art, so the ordering and groupings presented herein are not an exhaustive list of alternatives. Moreover, it should be recognized that the stages can be implemented in hardware, firmware, software or any combination thereof.

What is claimed is:

1. A method for refreshing a memory device, comprising:
at a memory device including a non-volatile memory, wherein the non-volatile memory includes a plurality of X-level memory cells, and X is equal to an integer number greater than 1:
applying a readout voltage based on a reference voltage to read data stored in the plurality of X-level memory cells, each of the plurality of X-level memory cells configured to store a respective one of a plurality of successive integer values;
based on the readout voltage, identifying a subset of memory cells of the plurality of memory cells storing a first value of the plurality of successive integer values, the first value being the largest integer value stored by the plurality of successive integer values; and
programming the subset of memory cells to re-write the first value in the subset of memory cells.

2. The method of claim 1, further comprising:
identifying a voltage range based on the reference voltage, wherein applying the readout voltage includes increasing the readout voltage in the voltage range; and
while increasing the readout voltage in the voltage range, determining that each of the subset of memory cells has a respective transistor that is switched from an off state to an on state.

3. The method of claim 1, further comprising:
aborting programming a remainder of the plurality of memory cells in a corresponding background data refresh, wherein the subset of the plurality of memory cells is programmed according to a background refresh rate.

4. The method of claim 1, wherein the plurality of X-level memory cells have a plurality of peak probabilities at a plurality of feature threshold voltages for storing the plurality of successive integer values, the method further comprising:
identifying the reference voltage in a range between two largest feature threshold voltages of the plurality of feature threshold voltages, wherein each of the subset of memory cells storing the first value has a respective threshold voltage greater than the reference voltage.

5. The method of claim 4, identifying the reference voltage further comprising:
determining a first number of memory cells storing the first value with respect to an associated threshold voltage in the range;
determining a second number of memory cells storing a second value with respect to an associated threshold voltage in the range, wherein the second value is the second largest value among the plurality of successive integer values; and
in accordance with a determination that the first number is equal to the second number at an intermediate threshold voltage, setting the reference voltage based on the intermediate threshold voltage.

6. The method of claim 4, wherein the reference voltage is an average of two largest feature threshold voltages of the plurality of feature threshold voltages.

7. The method of claim 4, wherein the reference voltage includes a first reference voltage, and a second reference voltage is greater than the first reference voltage, and each of the subset of the plurality memory cells storing the first value has a respective threshold voltage greater than the first reference voltage and less than the second reference voltage.

8. The method of claim 7, wherein the second reference voltage is equal to a first feature threshold voltage corresponding to the first value.

9. The method of claim 7, wherein the second reference voltage is less than a first feature threshold voltage corresponding to the first value.

10. The method of claim 7, wherein the second reference voltage is equal to or greater than a pass-through voltage configured to turn on all of the plurality of X-level memory cells.

11. The method of claim 1, wherein X is equal to 2, 3, 4, or 5, and each memory cell stores X data bits.

12. The method of claim 1, wherein X is equal to 3, 4, 8, 16, or 32.

13. The method of claim 1, wherein:
X is equal to 3, and the first value is equal to 7;
the memory device is a TCL-based memory flash; and
the plurality of memory cells includes an overall number of memory cells storing the first value in total; and
the subset of memory cells that is programmed includes a target number of memory cells, the target number being less than a half of the overall number.

14. A memory device, comprising:
a memory controller; and
a non-volatile memory, wherein the non-volatile memory includes a plurality of X-level memory cells, and X is equal to an integer number greater than 1;
memory storing one or more programs comprising instructions for:
applying a readout voltage based on a reference voltage to read data stored in the plurality of X-level memory cells, each of the plurality of X-level memory cells configured to store a respective one of a plurality of successive integer values;
based on the readout voltage, identifying a subset of memory cells of the plurality of memory cells storing a first value of the plurality of successive integer values, the first value being the largest integer value stored by the plurality of successive integer values; and
programming the subset of memory cells to re-write the first value in the subset of memory cells.

15. The memory device of claim 14, wherein the plurality of X-level memory cells have a plurality of peak probabilities at a plurality of feature threshold voltages for storing the plurality of successive integer values, the one or more programs further comprising instructions for:
identifying the reference voltage in a range between two largest feature threshold voltages of the plurality of feature threshold voltages, wherein each of the subset of memory cells storing the first value has a respective threshold voltage greater than the reference voltage.

16. The memory device of claim 15, identifying the reference voltage further comprising:
determining a first number of memory cells storing the first value with respect to an associated threshold voltage in the range;
determining a second number of memory cells storing a second value with respect to an associated threshold voltage in the range, wherein the second value is the second largest value among the plurality of successive integer values; and
in accordance with a determination that the first number is equal to the second number at an intermediate threshold voltage, setting the reference voltage based on the intermediate threshold voltage.

17. The memory device of claim 15, wherein the reference voltage is an average of two largest feature threshold voltages of the plurality of feature threshold voltages.

18. A non-transitory computer-readable storage medium storing one or more programs configured for execution by one or more processors of a memory device, the one or more programs comprising instructions for:
at the memory device, the memory device including a non-volatile memory having a plurality of X-level memory cells, X equal to an integer number greater than 1:
applying a readout voltage based on a reference voltage to read data stored in the plurality of X-level memory cells, each of the plurality of X-level memory cells configured to store a respective one of a plurality of successive integer values;
based on the readout voltage, identifying a subset of memory cells of the plurality of memory cells storing a first value of the plurality of successive integer values, the first value being the largest integer value stored by the plurality of successive integer values; and
programming the subset of memory cells to re-write the first value in the subset of memory cells.

19. The non-transitory computer-readable storage medium of claim 18, the one or more programs further comprising instructions for:
identifying a voltage range based on the reference voltage, wherein applying the readout voltage includes increasing the readout voltage in the voltage range; and
while increasing the readout voltage in the voltage range, determining that each of the subset of memory cells has a respective transistor that is switched from an off state to an on state.

20. The non-transitory computer-readable storage medium of claim 18, the one or more programs further comprising instructions for:
aborting programming a remainder of the plurality of memory cells in a corresponding background data refresh, wherein the subset of the plurality of memory cells is programmed according to a background refresh rate.
